(19) United States
(12) Patent Application Publication
(10) Pub. No.: US 2025/0181805 A1
(43) Pub. Date: Jun. 5, 2025

(54) SYSTEMS, METHODS, AND APPARATUSES FOR SMART FIELD DEVELOPMENT USING ARTIFICIAL INTELLIGENCE

(71) Applicant: ConocoPhillips Company, Houston, TX (US)

(72) Inventors: Hui Zhou, Houston, TX (US); Johan A. Daal, Houston, TX (US); Qin Lu, Houston, TX (US); Mazaruny Rincones, Houston, TX (US); Rafael E. Paz Lopez, Houston, TX (US)

(21) Appl. No.: 18/967,021

(22) Filed: Dec. 3, 2024

Related U.S. Application Data
(60) Provisional application No. 63/605,812, filed on Dec. 4, 2023.

(51) Int. Cl. G06F 30/28; G06F 30/27

(52) U.S. Cl. CPC G06F 30/28; G06F 30/27

(57) ABSTRACT

Implementations claimed and described herein provide systems and methods for optimizing well completion modeling. The systems and methods use an AI-driven modeling system with a plurality of different machine-learning components.

### CROSS-REFERENCE TO RELATED APPLICATIONS

The present application claims priority to U.S. Provisional Patent Application No. 63/605,812 filed on Dec. 4, 2023, which is incorporated by reference in its entirety herein.

### FIELD

Aspects of the present disclosure relate generally to systems and methods for modeling well completion.

### BACKGROUND

Unconventional reservoirs, such as shale gas reservoirs, shale oil reservoirs, and/or the like, are generally complex both in terms of geology and development. More particularly, shales are highly heterogeneous due to nanoscale pore size and highly variable structures. Characterizing shale geology in terms of permeability and natural fractures remains a pervasive challenge. Exacerbating these challenges, performance of an unconventional well is strongly driven by development approaches in drilling, well placement, and completion, and the technology to reliably characterize and model hydraulic fractures is insufficient. The insufficiencies of such conventional technologies are especially apparent given the inability to distinguish or quantify producible oil. For example, dynamic results from production often show a significantly different water cut than anticipated based on total water saturation estimates from traditional static formation evaluation models.

It is with these observations in mind, among others, that the presently disclosed technology was conceived.

### BRIEF DESCRIPTION OF THE DRAWINGS

FIG. 1 illustrates an example system of field development using an artificial intelligence framework.

FIG. 2 illustrates a flow diagram of a method of field development using an artificial intelligence framework, which can be performed by the systems disclosed herein.

FIG. 3 illustrates an example computing system that may implement various aspects of the system of field development.

### DETAILED DESCRIPTION

The complexity posed by multi-stacked heterogeneous reservoir, large-scale horizontal stimulation, and development induced well interactions creates challenges to optimizing the field development, which the disclosed technology addresses. For instance, aspects of the present disclosure involve systems and methods of generating and using an Artificial Intelligence (AI)-driven reservoir engineering workflow modeling system. This AI-driven reservoir engineering workflow modeling system can generate various target parameters which are used to optimize development strategies for unconventional reservoirs. In some examples, the techniques disclosed herein can handle challenges like complex well interactions, spanning parent, child, and co-completed wells across different benches.

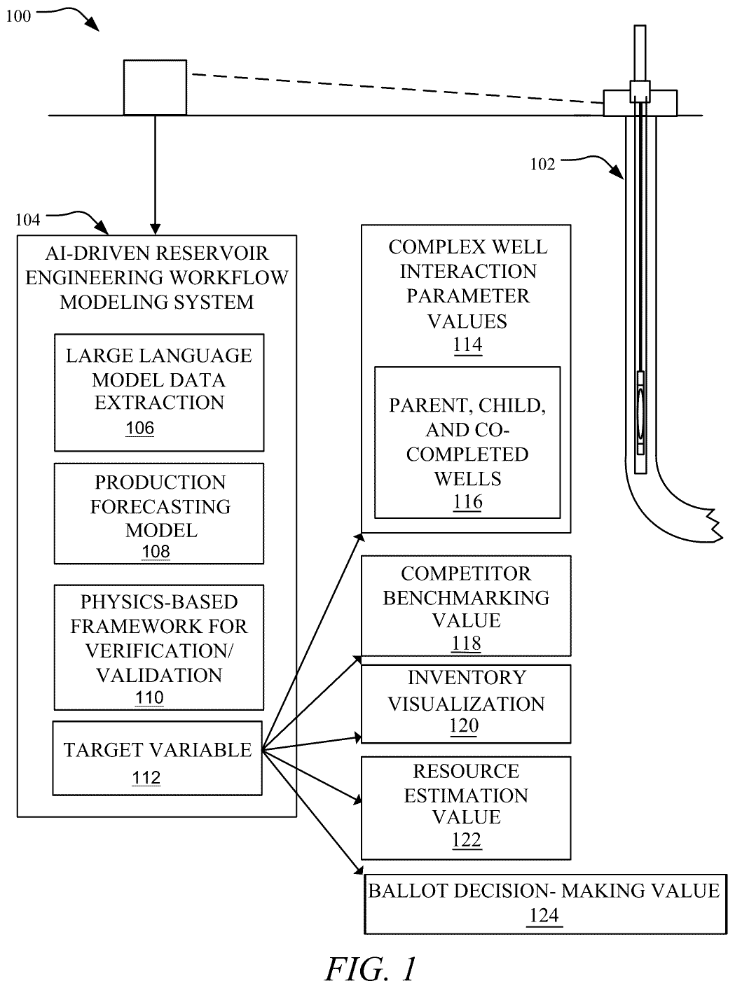

As depicted in FIG. 1, an example field development intelligence system 100 for optimization of development strategies for unconventional reservoirs. In an implementation, the system 100 includes one or more wells 102 used to extract oil or gas and an AI-driven reservoir engineering workflow modeling system 104 that forms part of an AI-driven modeling framework which can be founded on an integrated big data warehouse and/or on-demand capabilities for efficient visualization and analysis of heterogeneous data. It can encompass a plurality of purpose-built AI models working in tandem. Large language models (LLM) 106 can be employed to autonomously extract critical information from various sources, including well reports and/or communication documents. Machine learning models 108 can be used by the AI-driven reservoir engineering workflow modeling system for target variables 112 used for production forecasting based on historical data, and geology and performance metrics can be analyzed to characterize type curve areas. Finally, all this information can be integrated within a physics-based machine learning framework 110 to gain insights into reservoir quality, completion efficiency, and well interactions.

The technology disclosed herein can be used in a wide variety of different hydrocarbon regions aiming to enhance productivity and sustainability through improved modeling techniques. Additionally, this development of purpose-built machine learning models guided by engineering and physics intuition can represent an innovative, efficient, and reliable approach that extends its benefits to researchers and practitioners in the broader field of machine learning, transcending the boundaries of the oil and gas industry.

In some examples, this AI-driven reservoir engineering workflow modeling system focuses on optimizing development strategies for unconventional reservoirs. It can handle challenges like complex well interactions 114, spanning parent, child, and co-completed wells 116 across different benches. This workflow can integrate geological, production, and reservoir data to construct optimal strategies, making it a valuable asset for managing the multitude of wells operated by diverse operators in the basin.

This integrated workflow can yield a comprehensive and insightful field development intelligence system. Routine reservoir engineering tasks, such as competitor benchmarking 118, inventory visualization 120, resource estimation of existing producers 122, and ballot decision-making 124, can be greatly simplified. Furthermore, more complex tasks, such as field development optimization, can be achieved within the system by leveraging insights and quantitative predictions from the physics-inspired machine learning model.

In some examples, the use of the technology disclosed herein in the variety of different regions can serve as a testament to its potential to transform development strategies in the oil and gas industry, providing valuable lessons for other hydrocarbon regions aiming to enhance productivity and sustainability through this advanced technology. Additionally, this development of purpose-built machine learning models guided by engineering and physics verification and validation systems can represent an innovative, efficient, and reliable approach that can extend benefits to researchers and practitioners in the broader field of machine learning, transcending the boundaries of the oil and gas industry.

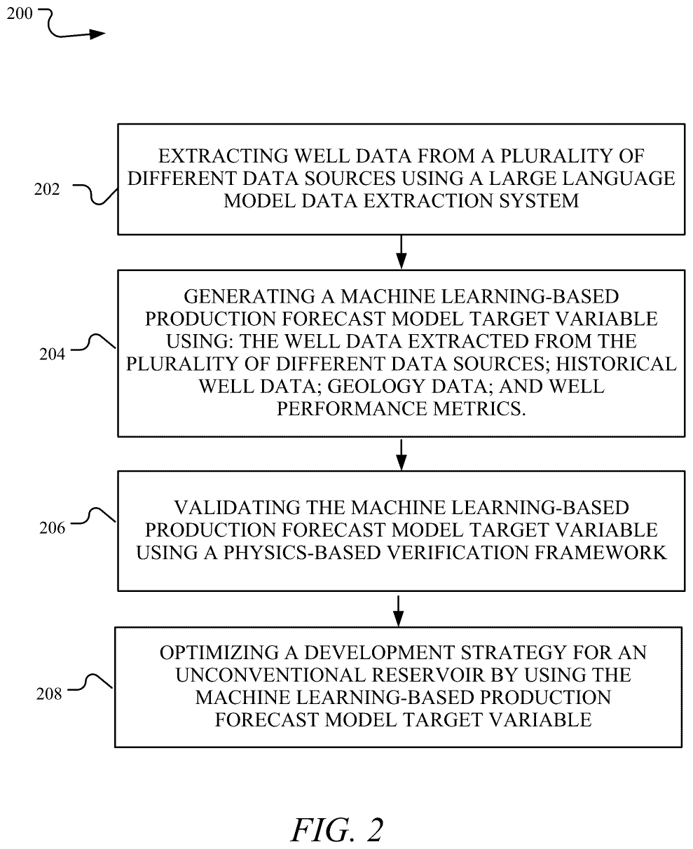

FIG. 2 depicts an example method 200 of performing reservoir engineering workflow modeling using an AI-driven modeling system(s) with a plurality of different machine-learning components, which can be performed by the systems disclosed herein. In some examples, at a first operation 202, the method can extract well data from a plurality of different data sources using a large language model data extraction system (e.g., a first machine learning system). At a second operation 204, the method can generate one or more machine learning-based production forecast model target variables (e.g., with a second machine-learning system) using: the well data extracted from the plurality of sources; historical well data; geology data; and/or well performance metrics. At a third operation 206, the method can validate the one or more production forecast model target variable using a physics-based verification framework (e.g., a third machine-learning system). At a fourth operation 208, the method can optimize a development strategy for an unconventional reservoir by using the machine learning-based production forecast model target variable.

In some examples, the AI-driven reservoir engineering workflow modeling system 104 can be implemented on a computing system having one or more computing units that may implement various systems and methods discussed herein is provided. The computing system may be applicable to the AI-driven reservoir engineering workflow modeling system, various systems or aspects of the AI-driven reservoir engineering workflow modeling system, and other computing or network devices or tools. It will be appreciated that specific implementations of these devices may be of differing possible specific computing architectures not all of which are specifically discussed herein but will be understood by those of ordinary skill in the art.

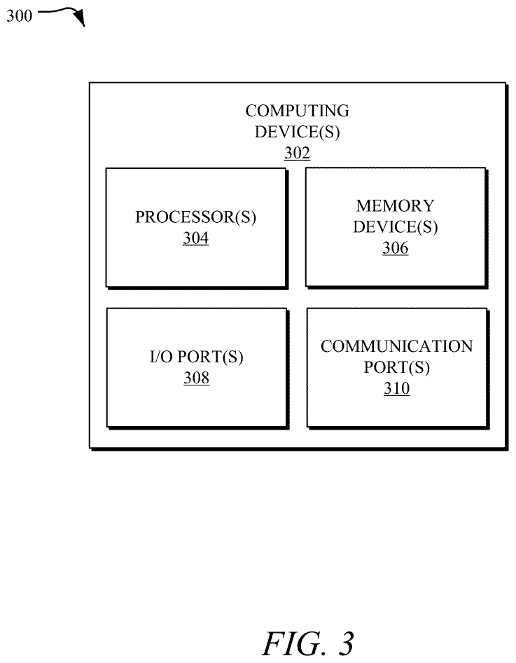

Turning to FIG. 3, a system 300 to process communication data can include one or more computing devices 302 for performing the techniques discussed herein. In one implementation, the one or more computing devices 302 include the AI-driven reservoir engineering workflow modeling system 104 to generate and execute LLM models 106, the production forecasting model 108, the physics-based machine learning framework 110, etc. as a software application and/or a module or algorithmic component of software.

In some instances, the computing device 302 can include a computer, a personal computer, a desktop computer, a laptop computer, a terminal, a workstation, a server device, a cellular or mobile phone, a mobile device, a smart mobile device a tablet, a wearable device (e.g., a smart watch, smart glasses, a smart epidermal device, etc.) a multimedia console, a television, an Internet-of-Things (IoT) device, a smart home device, a medical device, a virtual reality (VR) or augmented reality (AR) device, a vehicle (e.g., a smart bicycle, an automobile computer, etc.), and/or the like. The computing device 302 may be integrated with, form a part of, or otherwise be associated with the systems 100-300. It will be appreciated that specific implementations of these devices may be of differing possible specific computing architectures not all of which are specifically discussed herein but will be understood by those of ordinary skill in the art.

The computing device 302 may be a computing system capable of executing a computer program product to execute a computer process. Data and program files may be input to the computing device 302, which reads the files and executes the programs therein. Some of the elements of the computing device 302 include one or more processors 304, one or more memory devices 306, and/or one or more ports, such as input/output (IO) port(s) 308 and communication port(s) 310. Additionally, other elements that will be recognized by those skilled in the art may be included in the computing device 302 but are not explicitly depicted in FIG. 3 or discussed further herein. Various elements of the computing device 302 may communicate with one another by way of the communication port(s) 310 and/or one or more communication buses, point-to-point communication paths, or other communication means.

The processor 304 may include, for example, a central processing unit (CPU), a microprocessor, a microcontroller, a digital signal processor (DSP), and/or one or more internal levels of cache. There may be one or more processors 304, such that the processor 304 comprises a single central-processing unit, or a plurality of processing units capable of executing instructions and performing operations in parallel with each other, commonly referred to as a parallel processing environment.

The computing device 302 may be a conventional computer, a distributed computer, or any other type of computer, such as one or more external computers made available via a cloud computing architecture. The presently described technology is optionally implemented in software stored on the data storage device(s) such as the memory device(s) 306, and/or communicated via one or more of the I/O port(s) 308 and the communication port(s) 310, thereby transforming the computing device 302 in FIG. 3 to a special purpose machine for implementing the operations described herein. Moreover, the computing device 302, as implemented in the systems 100-300, receives various types of input data (e.g., the sensor data) and transforms the sensor data through various stages of the data flow into new types of data files (e.g., target variables). Moreover, these new data files are transformed further into output data to provide information regarding the data, which enables the computing device 302 to do something it could not do before—using a machine learning model to generate a machine learning based production forecast model target variable that is validated by a physics based verification framework to optimize a development strategy for an unconventional reservoir.

Additionally, the systems and operations disclosed herein represent an improvement to the technical field of machine learning processing. For instance, the AI-driven reservoir engineering workflow modeling system 104 can generate one or more target variable(s) from vast amounts of data from a plurality of production systems without human intervention and in real-time. Moreover, data can be leveraged to provide a highly efficient and effective productivity analysis of a large number or oil and gas production systems. These techniques are rooted in technology and could not have existed prior to the advent of machine learning analytics.

The one or more memory device(s) 306 may include any non-volatile data storage device capable of storing data generated or employed within the computing device 302, such as computer executable instructions for performing a computer process, which may include instructions of both application programs and an operating system (OS) that manages the various components of the computing device 302. The memory device(s) 306 may include, without limitation, magnetic disk drives, optical disk drives, solid state drives (SSDs), flash drives, and the like. The memory device(s) 306 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory device(s) 306 may include volatile memory (e.g., dynamic random access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the memory device(s) 306 which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computing device 302 includes one or more ports, such as the I/O port(s) 308 and the communication port(s) 310, for communicating with other computing, network, or vehicle computing devices. It will be appreciated that the I/O port 308 and the communication port 310 may be combined or separate and that more or fewer ports may be included in the computing device 302.

The I/O port 308 may be connected to an I/O device, or other device, by which information is input to or output from the computing device 302. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing device 302 via the I/O port 308. Similarly, the output devices may convert electrical signals received from the computing device 302 via the I/O port 308 into signals that may be sensed as output by a human, such as sound, light, and/or touch. The input device may be an alphanumeric input device, including alphanumeric and other keys for communicating information and/or command selections to the processor 304 via the I/O port 308. The input device may be another type of user input device including, but not limited to direction and selection control devices, such as a mouse, a trackball, cursor direction keys, a joystick, and/or a wheel; one or more sensors, such as a camera, a microphone, a positional sensor, an orientation sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

The environment transducer devices convert one form of energy or signal into another for input into or output from the computing device 302 via the I/O port 308. For example, an electrical signal generated within the computing device 302 may be converted to another type of signal, and/or vice-versa. In one implementation, the environment transducer devices sense characteristics or aspects of an environment local to or remote from the computing device 302, such as, light, sound, temperature, pressure, magnetic field, electric field, chemical properties, physical movement, orientation, acceleration, gravity, and/or the like.

In one implementation, the communication port 310 is connected to network(s) so the computing device 302 can receive network data useful in executing the methods and systems set out herein as well as transmitting information and network configuration changes determined thereby. Stated differently, the communication port 310 connects the computing device 302 to one or more communication interface devices configured to transmit and/or receive information between the computing device 302 and other devices by way of one or more wired or wireless communication networks or connections. Examples of such networks or connections include, without limitation, Universal Serial Bus (USB), Ethernet, Wi-Fi, Bluetooth®, Near Field Communication (NFC), and so on. One or more such communication interface devices may be utilized via the communication port 310 to communicate with one or more other machines, either directly over a point-to-point communication path, over a wide area network (WAN) (e.g., the Internet), over a local area network (LAN), over a cellular network (e.g., third generation (3G), fourth generation (4G), Long-Term Evolution (LTE), fifth generation (5G), etc.) or over another communication means. Further, the communication port 310 may communicate with an antenna or other link for electromagnetic signal transmission and/or reception.

In an example implementation, the AI-driven reservoir engineering workflow modeling system, the LLM data extraction model, the production forecasting model, the physics-based framework for verification/validation, software and other modules and services may be embodied by instructions stored on the data storage devices and/or the memory devices and executed by the processor. In an example, the AI-driven reservoir engineering workflow modeling system 104, the LLM data extraction model 106, the production forecasting model 108, the physics-based framework for verification/validation 110, etc., and/or other software, modules, services, and operations discussed herein may be embodied by instructions stored on the memory device(s) 306 and executed by the processor 304.

The system set forth in FIG. 3 is but one possible example of a computing device 302 or computer system that may be configured in accordance with aspects of the present disclosure. It will be appreciated that other non-transitory tangible computer-readable storage media storing computer-executable instructions for implementing the presently disclosed technology on a computing system may be utilized. In the present disclosure, the methods disclosed may be implemented as sets of instructions or software readable by the computing device 302.

In the description, phraseology and terminology are employed for the purpose of description and should not be regarded as limiting. For example, the use of a singular term, such as “a”, is not intended as limiting of the number of items. Also, the use of relational terms in the description for clarity in specific reference to the figures are not intended to limit the scope of the present inventive concept or the appended claims. Further, any one of the features of the present inventive concept may be used separately or in combination with any other feature. For example, references to the term “implementation” means that the feature or features being referred to are included in at least one aspect of the presently disclosed technology. Separate references to the term “implementation” in this description do not necessarily refer to the same implementation and are also not mutually exclusive unless so stated and/or except as will be readily apparent to those skilled in the art from the description. For example, a feature, structure, process, step, action, or the like described in one implementation may also be included in other implementations but is not necessarily included. Thus, the presently disclosed technology may include a variety of combinations and/or integrations of the implementations described herein. Additionally, all aspects of the presently disclosed technology as described herein are not essential for its practice.

Lastly, the terms “or” and “and/or” as used herein are to be interpreted as inclusive or meaning any one or any combination. Therefore, “A, B or C” or “A, B and/or C” mean any of the following: “A”; “B”; “C”; “A and B”; “A and C”; “B and C”; or “A, B and C.” An exception to this definition will occur only when a combination of elements, functions, steps or acts are in some way inherently mutually exclusive.

While the present disclosure has been described with reference to various implementations, it will be understood that these implementations are illustrative and that the scope of the present disclosure is not limited to them. Many variations, modifications, additions, and improvements are possible. More generally, embodiments in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A method for reservoir engineering workflow modeling, the method comprising:
extracting well data from a plurality of different data sources using a large language model data extraction system;
generating a machine learning-based production forecast model target variable using:
the well data extracted from the plurality of different data sources;
historical well data;
geology data; and
one or more well performance metrics; and
validating the machine learning-based production forecast model target variable using a physics-based verification framework.

2. The method of claim 1, wherein:
extracting the well data includes autonomously extracting information from at least one of well reports or communication documents associated with one or more wells.

3. The method of claim 1, wherein:
generating the machine learning-based production forecast model target variable includes generating a complex well interaction parameter value.

4. The method of claim 3, wherein:
the complex well interaction parameter value represents at least one of a child-parent well interaction or a co-completed well interaction.

5. The method of claim 1, wherein:
the machine learning-based production forecast model target variable includes a reservoir quality parameter value.

6. The method of claim 1, wherein:
the machine learning-based production forecast model target variable includes a competitor benchmark value.

7. The method of claim 1, wherein:
the machine learning-based production forecast model target variable includes a resource estimation value.

8. The method of claim 1, wherein:
the machine learning-based production forecast model target variable includes a ballot decision-making value.

9. The method of claim 1, further comprising:
generating, at a display of a computing device, an inventory visualization corresponding to the machine learning-based production forecast model target variable.

10. The method of claim 1, further comprising:
optimizing a development strategy for an unconventional reservoir using the machine learning-based production forecast model target variable.

11. The method of claim 10, wherein:
optimizing the development strategy for the unconventional reservoir includes integrating geological data, production data, and reservoir data via the large language model data extraction system.

12. A system for reservoir engineering workflow modeling, the system comprising:
a large language model data extraction system configured to extract well data from a plurality of different data sources;
a machine learning-based production forecast model configured to generate a production forecast target variable using the well data extracted from the plurality of different data sources, historical well data, geology data, and one or more well performance metrics; and
a physics-based verification framework system configured to validate the production forecast target variable.

13. The system of claim 12, wherein the well data is autonomously extracted information from at least one of a well report or a communication document associated with one or more wells.

14. The system of claim 12, wherein the production forecast target variable includes at least one of a reservoir quality parameter value, a competitor benchmark value, a resource estimation value, or a ballot decision-making value.

15. The system of claim 12, further comprising:
an output system configured to generate an inventory visualization corresponding to the production forecast target variable.

16. The system of claim 12, wherein the production forecast target variable is configured to be used to optimize a development strategy for an unconventional reservoir via the large language model data extraction system.

17. The system of claim 12, wherein the production forecast target variable is configured to be used to optimize a development strategy for an unconventional reservoir by integrating geological data, production data, and reservoir data via the large language model data extraction system.

18. The system of claim 12, wherein generating the production forecast target variable includes generating a complex well interaction parameter value.

19. The system of claim 18, wherein the complex well interaction parameter value represents at least one of a child-parent well interaction or a co-completed well interaction.
